(19) United States
(12) Patent Application Publication
(10) Pub. No.: US 2025/0372334 A1
(43) Pub. Date: Dec. 4, 2025

(54) EMITTER, ELECTRON GUN AND ELECTRONIC APPARATUS, AND EMITTER MANUFACTURING METHOD

(71) Applicant: Jie TANG, Ibaraki (JP)

(72) Inventors: Jie TANG, Ibaraki (JP); Shuai TANG, Ibaraki (JP); Wataru HAYAMI, Ibaraki (JP); Luchang QIN, Ibaraki (JP)

(21) Appl. No.: 18/874,090

(22) PCT Filed: Jun. 23, 2023
(86) PCT No.: PCT/JP2023/023417

§ 371 Date: Dec. 12, 2024

(30) Foreign Application Priority Data
Jun. 23, 2022 (JP) 2022-100768

(51) Int. Cl. H01J 1/304; C23C 22/82

(52) U.S. Cl. CPC H01J 1/3044; C23C 22/82; H01J 2201/30415; H01J 2201/30496

(57) ABSTRACT

The present invention provides an emitter capable of emitting electrons highly efficiently and stably for a long period of time, an electron gun and electronic apparatus using the emitter, and a method for manufacturing the emitter. An emitter equipped with a nanoneedle formed of a rare earth oxide represented by the general formula REOₓ (wherein RE is a rare earth element and 1≤x<1.5) is manufactured by carrying out a process of oxidizing the surface of a metal containing a rare earth element to form a film composed of a rare earth oxide represented by the general formula REOₓ (wherein RE is a rare earth element and 1≤x<1.5) and a process of working the film composed of the rare earth oxide into a needle shape using a focused ion beam.

### CROSS-REFERENCE TO RELATED APPLICATIONS

The present application is a National Phase of International Application No. PCT/JP2023/023417 filed Jun. 23, 2023, which claims the benefit of priority from the prior Japanese patent application No. 2022-100768 filed on Jun. 23, 2022.

### TECHNICAL FIELD

The present invention relates to an emitter, an electron gun and electronic apparatus using the emitter, and a method for manufacturing the emitter.

### BACKGROUND ART

An electron gun mounted on an electronic microscope has been improved in various ways to obtain high-resolution and high-brightness observation images. Among the electron guns used in electronic microscopes, field emission and Schottky type electron guns utilize the tunnel effect and Schottky effect, and efficiently emit electrons by generating an electric field concentration at the tip of an emitter.

As the emitter materials used in these electron guns, for example, low work function materials such as metal borides, such as lanthanum hexaboride (LaB₆), and/or rare earth oxides, such as lanthanum oxide (La₂O₃), yttrium oxide (Y₂O₃), gadolinium oxide (Gd₂O₃), and tantalum carbide (Dy₂O₃), are used (see Patent Literature 1). The present inventors have also proposed an emitter using hafnium carbide (HfC) (see Patent Literature 2).

### CITATION LIST

### Patent Literatures

Patent Literature 1: Japanese Laid-open Patent Application Publication No. 2008-16451
Patent Literature 2: International Publication WO2021/002305

### SUMMARY OF INVENTION

### Technical Problem

However, as the precision and performance of electronic microscopes improves, emitters with higher brightness and longer life are required.

Accordingly, an object of the present invention is to provide an emitter capable of emitting electrons highly efficiently and stably over a long period of time, an electron gun and electronic apparatus using the emitter, and a method for manufacturing the emitter.

### Solution to Problem

The emitter according to the present invention is an emitter equipped with a nanoneedle, the nanoneedle being formed of a rare earth oxide represented by the general formula REOₓ (wherein, RE is a rare earth element and 1≤x<1.5).

At least the tip of the nanoneedle may be composed of a crystalline phase. In this case, the crystalline phase may be at least one crystal system selected from the group consisting of, for example, a cubic crystal system, a monoclinic crystal system, and a hexagonal crystal system. When the crystalline phase is a cubic crystal system, the crystal plane of the tip of the nanoneedle may be a (001) plane or a (110) plane, when the crystalline phase is a monoclinic crystal system, the crystal plane of the tip of the nanoneedle may be a (010) plane, and when the crystalline phase is a hexagonal crystal system, the crystal plane of the tip of the nanoneedle may be a (102 ) plane.

The rare earth oxide may contain at least one rare earth element selected from the group consisting of La, Ce, Pr, Nd, and Sm.

The rare earth oxide may contain Ga in an amount of 0.5 atomic % or less.

On the other hand, the nanoneedle may have a maximum diameter of 1 nm or more and 1 μm or less and a length of 500 nm or more and 30 μm or less. In this case, the curvature radius of the tip of the nanoneedle may be 50% or less of the maximum diameter. The curvature radius of the tip of the nanoneedle may be 5 to 30 nm.

The emitter of the present invention may further comprise a support needle and a filament, the support needle being made of at least one element selected from the group consisting of W, Ta, Pt, Re and C, and the nanoneedle being attached to the filament via the support needle.

The electron gun according to the present invention includes the above-mentioned emitter, and is, for example, a cold cathode field emission electron gun or a Schottky electron gun.

The electronic apparatus according to the present invention is equipped with an electron gun, and is, for example, a scanning electronic microscope, a transmission electronic microscope, a scanning transmission electronic microscope, an Auger electron spectrometer, an electron energy loss spectrometer, and an energy dispersive electron spectrometer.

The method for manufacturing an emitter according to the present invention is a method for manufacturing an emitter equipped with a nanoneedle, and includes a process of oxidizing the surface of a metal containing a rare earth element to form a film made of a rare earth oxide represented by the general formula REOₓ (wherein RE is a rare earth element and 1≤x<1.5), and a process of working the film made of the rare earth oxide into a needle shape using a focused ion beam to obtain the nanoneedle.

In the process of forming the film made of the rare earth oxide, the surface of a metal containing a rare earth element may be oxidized by maintaining the metal under conditions of a temperature of 0 to 800° C., a pressure of 10¹ to 10⁵ Pa, and a relative humidity of 10 to 70%.

In the process of working the film made of the rare earth oxide into a needle shape, the film made of the rare earth oxide may be cut out from the surface of the metal, and the film made of the rare earth oxide may be placed on a support needle.

### Advantageous Effects of Invention

According to the present invention, an emitter and an electron gun that can emit electrons highly efficiently and stably over a long period of time are obtained.

### BRIEF DESCRIPTION OF DRAWINGS

FIG. 1 is a schematic view showing a configuration example of an emitter according to a first embodiment of the present invention.

FIG. 2 is a schematic view showing the configuration of a nanoneedle 10 shown in FIG. 1.

FIG. 3 is a flowchart showing an example of a manufacturing process for the emitter according to the first embodiment of the present invention.

FIG. 4 is a view schematically illustrating the configuration of an electron gun according to a second embodiment of the present invention.

FIG. 5 is a view showing the density of electronic states (DOS) of LaO.

FIGS. 6A to 6D are views of the density of electronic states (DOS) of LaOx (x=1.4165 or x=1.4375) with different crystal systems.

FIGS. 7A and 7B are views showing the results of a molecular dynamics simulation.

FIG. 8A is a SEM image of a LaOx nanoneedle, and FIG. 8B is a TEM image.

FIGS. 9A to 9C are views showing STEM-EDS mapping of a LaOx nanoneedle.

FIG. 10 is a view showing the field emission pattern of a LaOx nanoneedle.

FIGS. 11A and 11B are views showing the current stability of a LaOx nanoneedle.

### DESCRIPTION OF EMBODIMENTS

Hereinafter, embodiments for carrying out the present invention will be described in detail with reference to the accompanying drawings. Note that the present invention is not limited to the following embodiments.

### First Embodiment

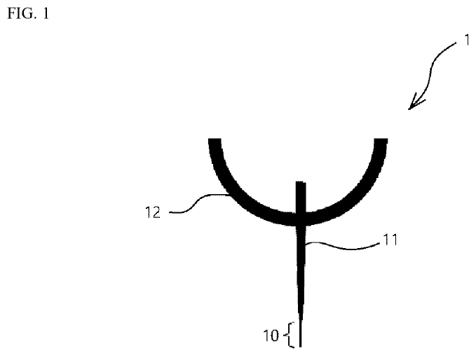

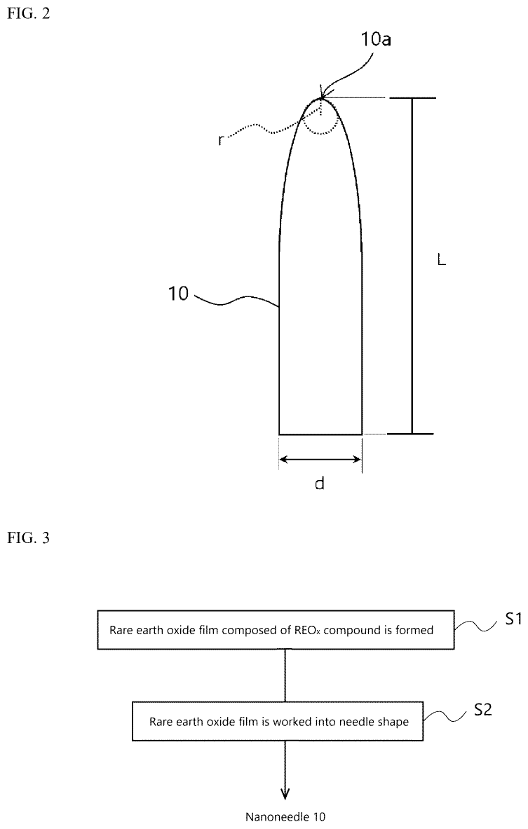

First, an emitter according to a first embodiment of the present invention will be described. FIG. 1 is a schematic view showing a configuration example of the emitter of this embodiment, and FIG. 2 is a schematic view showing the configuration of the nanoneedle 10 shown in FIG. 1. As shown in FIG. 1, the emitter 1 of this embodiment is equipped with a nanoneedle 10. The nanoneedle 10 is formed of a rare earth oxide represented by the general formula REOx (RE is a rare earth element) where 1≤x<1.5.

[REOₓ (where 1≤x<1.5)]

The present inventors have conducted extensive research into rare earth oxides and have found that compounds represented by the general formula REOₓ (hereinafter also referred to as REOₓ compounds) have a low work function and excellent electron emission capability. In particular, it have been found that rare earth oxides (REO) where x=1 and RE is divalent, and rare earth oxides (RE₂O₃) where x=1.5 and RE is trivalent, with oxygen deficiency introduced (1<x<1.5), have improved electrical conductivity and a low work function.

The REOₓ compound is preferably one in which 1<x<1.5 from the standpoint of chemical stability. Further, the REOₓ compound is more preferably one in which 1.2≤x<1.5, since it has a low work function and is excellent in electron emission capability. Even more preferably, the REOₓ compound is one in which 1.4≤x≤1.49, which is particularly chemically stable, has a lower work function, and is excellent in electron emission capability.

The rare earth element (RE) of the REOₓ compound is not particularly limited, but is preferably at least one selected from the group consisting of lanthanum (La), cerium (Ce), praseodymium (Pr), neodymium (Nd) and samarium (Sm). By using an REOx compound composed of these rare earth elements, a work function of 2.7 eV or less can be achieved. The rare earth element (RE) of the REOx compound is particularly preferably lanthanum (La), and by forming the nanoneedle 10 from lanthanum oxide, an emitter with a work function of 1.8 to 2.3 eV and excellent electron emission capability can be obtained.

The REOₓ compound forming the nanoneedle 10 may further contain gallium (Ga). This allows the electrons to be emitted stably for a long period of time. In this case, the amount of Ga in the REOₓ compound is preferably more than 0 atomic % and not more than 5 atomic % from the viewpoint of maintaining the crystal structure.

The REOₓ compound forming the nanoneedle 10 may be entirely composed of a crystalline phase or an amorphous phase, or may be composed of both a crystalline phase and an amorphous phase, but it is preferable that the tip 10a of the nanoneedle 10 that emits electrons is composed of a crystalline phase. This provides an excellent emitter that can stably emit electrons.

Here, the crystalline phase of the REOₓ compound composing the nanoneedle 10 may be either single crystal or polycrystal, but polycrystal is preferable because it is easy to manufacture. The crystalline phase of the REOₓ compound may be at least one type of crystal system selected from the group consisting of a cubic crystal system, a monoclinic crystal system, and a hexagonal crystal system.

Hereinafter, the crystal system will be described using the case where the rare earth element (RE) is lanthanum (La) (LaOₓ) as an example. When x=1 in LaOₓ, that is, LaO is a crystal having a crystal structure of cubic crystal system as shown in Table 1 below, and belonging to the Fm3 m space group (space group No. 225 of International Tables for Crystallography). Note that “3 ” indicates that 3 is overlined, and the same applies in the following description. In addition, in the case of LaO, it is preferable that the lattice constant a (nm) is 0.45<a<0.55, since the crystal structure is stable.

TABLE 1

| Crystal composition | LaO |
|---|---|
| Formula weight (Z) | 4 |
| Crystal system | Cubic crystal |
| Space group | Fm3̅m |
| Space group No. | 225 |

| | | | |
|---|---|---|---|
| Lattice constant | a | 0.5144 | nm |
| | b | 0.5144 | nm |
| | c | 0.5144 | nm |
| | α | 90 | Degree |
| | β | 90 | Degree |
| | γ | 90 | Degree |

| | Atomic coordinate | | | Coordinate |
|---|---|---|---|---|
| Atom | x | y | z | occupancy rate |
| O | ½ | ½ | ½ | 1 |
| La | 0 | 0 | 0 | 1 |

On the other hand, when 1<x<1.5 in LaOx, it has either a cubic, hexagonal or monoclinic crystal structure. When the crystal structure of LaOx is a cubic crystal system, it is a crystal belonging to the Ia3 space group (space group No. 206 of International Tables for Crystallography) shown in Table 2 below, or the Im3 m space group (space group No. 229 of International Tables for Crystallography) shown in Table 3 below.

TABLE 2

| Crystal composition | La₂O₃ |
|---|---|
| Formula weight (Z) | 16 |
| Crystal system | Cubic crystal |
| Space group | Ia3̅ |
| Space group No. | 206 |

| | | | |
|---|---|---|---|
| Lattice constant | a | 1.1414 | nm |
| | b | 1.1414 | nm |
| | c | 1.1414 | nm |
| | α | 90 | Degree |
| | β | 90 | Degree |
| | γ | 90 | Degree |

| | Atomic coordinate | | | Coordinate |
|---|---|---|---|---|
| Atom | x | y | z | occupancy rate |
| O | 0.089 | 0.358 | 0.102 | 1 |
| La (1) | 0.267 | 0 | ¼ | 1 |
| La (2) | 0 | 0 | 0 | 1 |

TABLE 3

| Crystal composition | La₂O₃ |
|---|---|
| Formula weight (Z) | 2 |
| Crystal system | Cubic crystal |
| Space group | Im3̅m |
| Space group No. | 229 |

| | | | |
|---|---|---|---|
| Lattice constant | a | 0.451 | nm |
| | b | 0.451 | nm |
| | c | 0.451 | nm |
| | α | 90 | Degree |
| | β | 90 | Degree |
| | γ | 90 | Degree |

| | Atomic coordinate | | | Coordinate |
|---|---|---|---|---|
| Atom | x | y | z | occupancy rate |
| O | 0.18 | 0 | ½ | 0.125 |
| La | 0 | 0 | 0 | 1 |

In the case of crystals belonging to the Ia3 space group, the lattice constant a (nm) is preferably 1.10<a<1.20, and in the case of crystals belonging to the Im3 m space group, the lattice constant a is preferably 0.43 nm<a<0.47 nm. This stabilizes the crystal structure.

Furthermore, as shown in Table 4 below, when LaOₓ has a crystal structure of hexagonal crystal system, it may be a crystal belonging to the P3 m1 space group (space group No. 164 of International Tables for Crystallography). In this case, the lattice constant a (nm) is preferably 0.37<a<0.41, and the lattice constant c (nm) is preferably 0.58<c<0.64. This allows a smaller work function to be achieved in LaOₓ having a crystal structure of hexagonal crystal system.

TABLE 4

| Crystal composition | La₂O₃ |
|---|---|
| Formula weight (Z) | 1 |
| Crystal system | Hexagonal crystal |
| Space group | P3̅m1 |
| Space group No. | 164 |

| | | | |
|---|---|---|---|
| Lattice constant | a | 0.394 | nm |
| | b | 0.394 | nm |
| | c | 0.613 | nm |
| | α | 90 | Degree |
| | β | 90 | Degree |
| | γ | 120 | Degree |

| | Atomic coordinate | | | Coordinate |
|---|---|---|---|---|
| Atom | x | y | z | occupancy rate |
| La | ⅓ | ⅔ | 0.247 | 1 |
| O (1) | ⅓ | ⅔ | 0.647 | 1 |
| O (2) | 0 | 0 | 0 | 1 |

Furthermore, as shown in Table 5 below, when LaOₓ has a crystal structure of monoclinic crystal system, it may be a crystal belonging to the C2/m space group (space group No. 12 of International Tables for Crystallography). In this case, it is preferable that the lattice constant a (nm) is 1.40<a<1.50, the crystal constant b is 0.30<b<0.40, and the lattice constant c (nm) is 0.85<c<0.95. This stabilizes the crystal structure.

TABLE 5

| Crystal composition | La₂O₃ |
|---|---|
| Formula weight (Z) | 6 |
| Crystal system | Monoclinic crystal |
| Space group | C2/m |
| Space group No. | 12 |

| | | | |
|---|---|---|---|
| Lattice constant | a | 1.442 | nm |
| | b | 0.3722 | nm |
| | c | 0.9109 | nm |
| | α | 90 | Degree |
| | β | 99.73 | Degree |
| | γ | 90 | Degree |

| | Atomic coordinate | | | Coordinate |
|---|---|---|---|---|
| Atom | x | y | z | occupancy rate |
| O (1) | 0.0259 | 0 | 0.6562 | 1 |
| La (1) | 0.13463 | 0 | 0.49003 | 1 |
| La (2) | 0.18996 | 0 | 0.13782 | 1 |
| O (2) | 0.2894 | 0 | 0.3738 | 1 |
| O (3) | 0.325 | 0 | 0.0265 | 1 |
| La (3) | 0.46627 | 0 | 0.18794 | 1 |
| O (4) | 0.6289 | 0 | 0.2864 | 1 |
| O (5) | 0 | 0 | 0 | 1 |

In the REOₓ compound, when the rare earth element (RE) is an element other than La or when some of the constituent elements are replaced with other elements, the lattice constant changes, but the crystal structure, the sites occupied by the atoms, and the atomic positions given by the coordinates do not change so much that the chemical bonds between the skeletal atoms are broken. Therefore, if the length of the RE-O chemical bond (the distance between adjacent atoms) calculated from the lattice constant obtained by Rietveld analysis of the results of X-ray diffraction or neutron diffraction in the above-mentioned space group is within ±5% of the length of the chemical bond calculated from the lattice constant and atomic coordinates of the crystal shown in Tables 1 to 5 above, the REOₓ compound forming the emitter of this embodiment can be considered to have the same crystal structure.

When the REOₓ compound is composed of a crystalline phase, the above-mentioned crystalline phases may be combined. In this case, the diffraction peak positions (2θ) calculated using the crystal structure parameters shown in Tables 1 to 5 above can be compared with the X-ray diffraction results of the REOₓ compound forming the emitter, and the main phase and secondary phase can be identified based on the agreement or deviation of the main peaks.

Furthermore, when the REOₓ compound at the tip 10a of the nanoneedle 10 has a crystalline phase of cubic crystal system, its crystal plane preferably has a (001) or (110) plane. Specifically, when the tip 10a of the nanoneedle 10 is formed of REOₓ (x=1), the crystal plane is preferably a (001) plane, and in the case of REOₓ (1<x<1.5, space group Ia3 ), the crystal plane is preferably a (110) plane, and in the case of REOₓ(1<x<1.5, space group Im3 m), the crystal plane is preferably a (001) plane.

On the other hand, when the REOₓ compound at the tip 10a of the nanoneedle 10 has a crystalline phase of hexagonal crystal system, its crystal plane is preferably a (102 ) plane. Note that “2 ” indicates that 2 is overlined, and the same applies in the following explanation. Also, for example, when the REOₓ compound at the tip 10a of the nanoneedle 10 has a crystalline phase of monoclinic crystal system, its crystal plane is preferably a (010) plane. These crystal planes are chemically stable, so by forming the tip 10a with these crystal planes, electrons can be efficiently emitted.

The above-mentioned crystal planes are merely examples, and the crystal planes of the tip 10a of the nanoneedle 10 are not limited to these. In principle, any crystal plane represented by a Miller index of 3 or less can be used. Here, “Miller index of 3 or less” means that the absolute value of each value is 3 or less.

### [Size of Nanoneedle 10]

For the nanoneedle 10, the maximum diameter d shown in FIG. 2 is preferably 1 nm or more and 1 μm or less, and its length L is preferably 500 nm or more and 30 μm or less. By setting the size of the nanoneedle 10 within this range, an electric field can be efficiently concentrated at the tip 10a from which electrons are to be emitted, and more electrons can be emitted from the tip 10a of the nanoneedle 10.

The maximum diameter d of the nanoneedle 10 is more preferably 400 to 800 nm, and its length L is more preferably 1 to 3 μm. The nanoneedle 10 in this size range is easy to work, and therefore makes it possible to manufacture an emitter with a good yield.

On the other hand, the nanoneedle 10 has a shape that tapers (the diameter becomes smaller) toward the peak, and the curvature radius r of the tip 10a is preferably 50% or less of the maximum diameter d. This allows electrons to be efficiently emitted from the tip 10a. From the viewpoint of improving the electron emission efficiency, the curvature radius d of the tip 10a of the nanoneedle 10 is more preferably 1 to 10% of the maximum diameter d, and even more preferably 1 to 5%.

The value of the curvature radius r of the tip 10a of the nanoneedle 10 is not particularly limited and can be adjusted appropriately depending on the application of the emitter, but from the viewpoint of electric field concentration, it is preferably 0.5 to 75 nm, more preferably 5 to 50 nm, even more preferably 10 to 30 nm, and particularly preferably 15 to 25 nm. For example, when the emitter of this embodiment is used in an electron gun, the value of the curvature radius r of the tip 10a of the nanoneedle 10 is preferably 5 to 50 nm from a practical viewpoint.

The shape and curvature radius r of the tip 10a of the nanoneedle 10 described above can be confirmed by observation with a scanning electronic microscope (SEM). The method for working and treating the tip 10a of the nanoneedle 10 into the above-mentioned shape is not particularly limited, but for example, an ion beam method or a field evaporation method can be applied. In particular, the method using a focused ion beam is preferable because Ga can be added to the REOₓ compound.

### [Other Configurations]

The emitter 1 of this embodiment may include a support needle 11 and a filament 12 in addition to the nanoneedle 10 described above, and in this case, the nanoneedle 10 is attached to the filament 12 via the support needle 11. This improves the ease of handling of the nanoneedle 10.

The support needle 11 may be made of at least one element selected from the group consisting of, for example, tungsten (W), tantalum (Ta), platinum (Pt), rhenium (Re) and carbon (C). The shape of the filament 12 shown in FIG. 1 is a hairpin shape (U-shape), but the present invention is not limited to this, and any shape such as a V-shape may be adopted.

### [Manufacturing Method]

Next, a method for manufacturing an emitter of this embodiment will be described. FIG. 3 is a flow chart showing an example of the manufacturing process of the emitter of this embodiment. As shown in FIG. 3, the method for manufacturing an emitter of this embodiment carries out a process of forming a rare earth oxide film made of an REOₓ compound (step S1) and a process of working the rare earth oxide film into a needle shape (step S2), to form a nanoneedle 10.

### [Step S1: Rare Earth Oxide Film Formation Process]

In step S1, the surface of a metal containing a rare earth element (RE) is oxidized to form a thin film made of a rare earth oxide represented by the general formula REOₓ (RE is a rare earth element) where 1≤x<1.5. The thickness of the rare earth oxide film formed here is preferably 2 μm or more, taking into account the workability in step S2.

The metal containing a rare earth element (RE) used here may be a metal consisting of one type of rare earth element (RE) or an alloy containing two or more types of rare earth elements (RE). In addition, the surface of the metal on which the rare earth oxide film is formed is preferably grinding-processed, so that a uniform rare earth oxide film can be formed.

The method and conditions for oxidizing the metal surface can be appropriately selected depending on the type of rare earth element (RE) contained in the metal, and for example, the metal may be held at a temperature of 0 to 800° C., at a vacuum of 10¹ to 10⁵ Pa, and at a relative humidity of 10 to 70%. The holding time at this condition varies depending on the thickness of the oxide film, but in order to obtain an oxide film having a thickness of 2 μm or more, the holding time may be in the range of 1 hour to 30 days. For example, in the case of forming polycrystalline LaOₓ (where 1<x<1.5) having a thickness of 2 to 3 μm, tthet metal may be held at room temperature (under an atmosphere of temperatures 10 to 30° C.) under environments of a vacuum of 50 to 150 Pa and a relative humidity of 30 to 55% for 1 to 3 weeks.

### [Step S2: Rare Earth Oxide Film Working Process]

In step S2, the rare earth oxide film formed in step S1 is worked into a needle shape using, for example, a focused ion beam. In this case, prior to the irradiation of a focused ion beam, the rare earth oxide film formed in step S1 may be cut out from the surface of the metal and placed on a support needle. This can improve the workability. Note that the support needle used here may also have the function of the support needle 11 shown in FIG. 1.

The conditions for irradiating a focused ion beam are not particularly limited, and for example, when gallium (Ga) ions are used, the following conditions can be adopted.
Current: 5 to 1000 pA (preferably, 500 to 900 pA)
Voltage: 1 to 100 kV (preferably, 20 to 40 kV)
Irradiation time: 1 to 60 minutes (preferably, 5 to 15 minutes)

When the nanoneedle 10 is worked into a shape that tapers toward the tip (has a smaller diameter), a focused ion beam may be irradiated so as to scan the rare earth oxide film from the outside to the inside.

As described above in detail, the emitter of this embodiment is equipped with a nanoneedle composed of a rare earth oxide represented by the general formula REOₓ(wherein RE is a rare earth element) in which 1≤x<1.5, therefore has a low work function and excellent electron emission capability. By using the emitter of this embodiment, it is possible to realize an electron gun and electronic apparatus that can stably emit electrons for a long period of time.

Furthermore, in the method for manufacturing an emitter of this embodiment, the surface of a metal containing a rare earth element (RE) is oxidized to form a rare earth oxide film represented by the general formula REOₓ, where 1≤x<1.5, and this oxide film is worked into a needle shape using a focused ion beam, so that a nanoneedle made of an REOₓ compound can be easily formed.

Since the emitter of the present embodiment can emit electrons efficiently and stably, it can be suitably used in any apparatuses having an electron focusing capability, such as a scanning electronic microscope, a transmission electronic microscope, a scanning transmission electronic microscope, an Auger electron spectrometer, an electron energy loss spectrometer, and an energy dispersive electron spectrometer.

### Second Embodiment

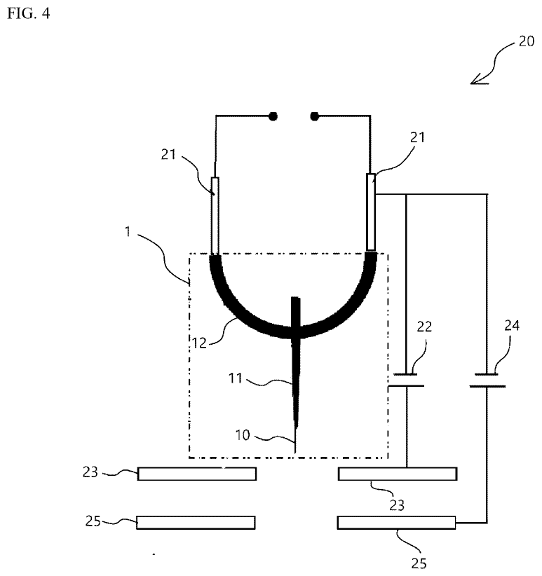

Next, an electron gun according to an embodiment of the present invention will be described. FIG. 4 is a view schematically showing an example of the configuration of an electron gun according to this embodiment. As shown in FIG. 4, an electron gun 20 according to this embodiment is, for example, a cold cathode field emission electron gun or a Schottky electron gun, and has the emitter 1 according to the first embodiment described above.

In the electron gun 20 of this embodiment, an extraction power source 22 is connected between the electrode 21 and the extraction electrode 23, and an acceleration power source 24 is connected between the electrode 21 and the acceleration electrode 25. The extraction power source 22 applies a voltage between the emitter 1 and the extraction electrode 23, and the acceleration power source 24 applies a voltage between the emitter 1 and the acceleration electrode 25. If the electron gun 20 is a cold cathode field emission electron gun, the electrode 21 may be further connected to a flash power source (not shown), and if the electron gun 20 is a Schottky electron gun, the electrode 21 may be further connected to a heating power source (not shown).

The electron gun 20 of this embodiment may be placed under vacuum conditions with a pressure of 10⁻⁸ to 110⁻⁷ Pa. This allows the tip 10a of the nanoneedle 10 of the emitter 1, from which electrons are emitted, to be kept clean.

### [Operation]

Next, the operation of the electron gun 20 of this embodiment will be described. When the electron gun 20 is a cold cathode field emission electron gun, a voltage is applied between the emitter 1 and the extraction electrode 23 by the extraction power source 22. This causes an electric field concentration at the tip 10a of the nanoneedle 10 of the emitter 1, and electrons are extracted. In addition, a voltage is applied between the emitter 1 and the acceleration electrode 25 by the acceleration power source 24. This causes electrons extracted at the tip 10a of the nanoneedle 10 of the emitter 1 to be accelerated, and the electrons are emitted toward the sample.

When the electron gun 20 is a cold cathode field emission electron gun, the surface of the nanoneedle 10 may be cleaned by performing appropriate lashing using a flash power source connected to the electrode 21. These operations are preferably performed under the above-mentioned vacuum conditions.

On the other hand, when the electron gun 20 is a Schottky electron gun, a heating power source connected to an electrode 21 heats the emitter 1, and the extraction power source 22 applies a voltage between the emitter 1 and an extraction electrode 23. This causes Schottky emission at the tip 10a of the nanoneedle 10 of the emitter 1, and electrons are extracted. In addition, the acceleration power source 24 applies a voltage between the emitter 1 and an acceleration electrode 25. This causes electrons extracted at the tip 10a of the nanoneedle 10 of the emitter 1 to be accelerated, and the electrons are emitted toward the sample.

These operations are preferably performed under the vacuum conditions described above. In the above-described configuration, since thermoelectrons may be emitted from the nanoneedle 10 of the emitter 1 due to the application of a voltage by the heating power source, the electron gun 20 may be further provided with a suppressor (not shown) for blocking thermoelectrons.

As described above in detail, the electron gun of this embodiment is equipped with the emitter of the first embodiment, and therefore can easily emit electrons and can emit electrons stably for a long period of time. The electron gun of this embodiment can be used in any electronic apparatus having an electron focusing capability. Specifically, it can be applied to electronic apparatuses such as scanning electronic microscopes, transmission electronic microscopes, scanning transmission electronic microscopes, Auger electron spectrometers, electron energy loss spectrometers, and energy dispersive electron spectrometers.

### EXAMPLES

The effects of the present invention will be described below specifically with reference to examples.

### First Example

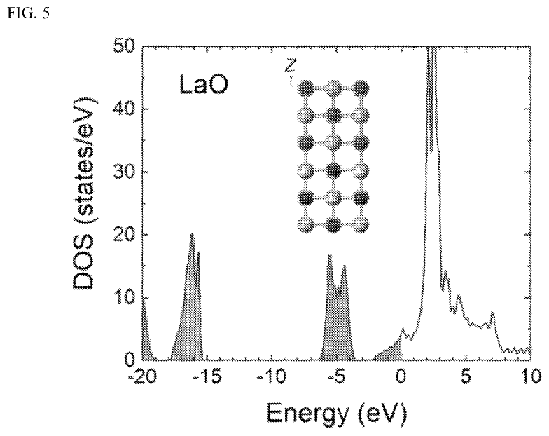

First, as a first example of the present invention, the electronic state and work function of an REOₓ compound in which the rare earth element (RE) is La, Ce, Pr, Nd, or Sm and x=1 were calculated by the first-principle calculation. The calculation was based on the density functional method, and an ultrasoft pseudopotential was used with a plane wave as the basis function. The density gradient approximation was adopted, and the cutoff energy of the plane wave was set to 80 Ry. The work function was calculated from the difference between the vacuum level and the Fermi level. For these calculations, Quantum Espresso v7.0 (downloaded from https://www.quantum-espresso.org) was used. The results are shown in Table 6 below. In addition, FIG. 5 is a view showing the density of electronic states (DOS) of LaO.

TABLE 6

| REOx (x = 1) | Work function (eV) |
|---|---|
| RE = La | 2.3 |
| RE = Ce | 2.3 |
| RE = Pr | 2.4 |
| RE = Nd | 2.7 |
| RE = Sm | 2.6 |

As shown in FIG. 4, the electronic state of LaO is metallic, and the work function of its (001) plane was calculated to be 2.3 eV from the calculated difference between the Fermi level and the vacuum level. Like LaO, the density of electronic states of CeO, PrO, NdO, and SmO was also metallic, and the work function was calculated to be 2.7 eV or less. In addition, as shown in Table 6 above, when the rare earth element (RE) was La and Ce, a low work function comparable to the work function (2.3 eV) of LaB₆ was obtained. From this, it was confirmed that the REOₓ compound with x=1 is a material that functions as an emitter.

### Second Example

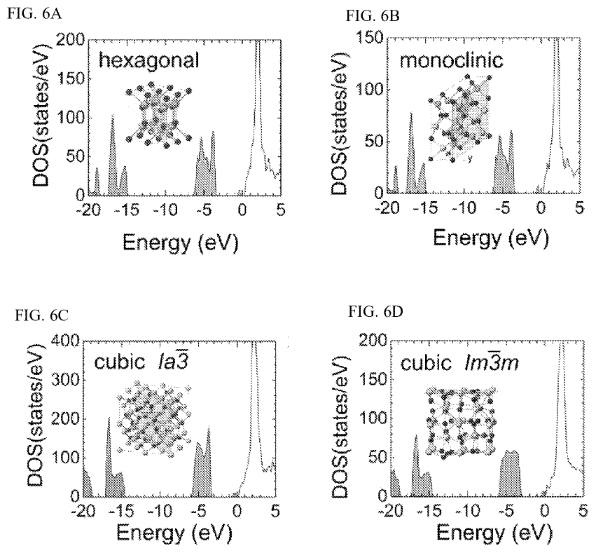

Next, as a second example of the present invention, the electronic state and work function of LaOₓ (x=1.4165 to 1.4375) were calculated by the first-principle calculation in the same manner as in the first example described above. The results are shown in Table 7 below. Table 7 below also shows the values of the work function of LaO and LaB₆ shown in Table 6 above together. Further, FIGS. 6A to 6D are views of the density of electronic states (DOS) of LaOₓ (x=1.4165 or x=1.4375) having different crystal systems.

TABLE 7

| | | Work | |
|---|---|---|---|
| | | function | |
| Compound | Crystal system | (eV) | Surface |
| LaOx (x = 1) | Cubic crystal | 2.3 | (001) |
| LaOx (x = 1.4375) | Hexagonal crystal | 1.8 | (10̅2), (110) |
| LaOx (x = 1.4165) | Monoclinic crystal | 2.0 | (010) |
| LaOx (x = 1.4375) | Cubic crystal (Ia3̅) | 1.9 | (110) |
| LaOx (x = 1.4375) | Cubic crystal (Im3̅m) | 2.1 | (001) |
| LaB6 | Cubic crystal | 2.3 | (001) |

As shown in FIGS. 6A to 6D, in all the crystal systems, oxygen defect levels occur near the bottom of the conductor, so that the electronic state of LaOₓ was metallic. Furthermore, as shown in Table 7 above, when 1<x<1.5 in LaOₓ, that is, when there is oxygen deficiency in La₂O₃, the work function is 1.8 to 2.1 eV, which is a lower value than that of LaB₆. From this, it was confirmed that REOₓ compounds with 1≤x<1.5 are materials that function as emitters, and that REOₓ compounds that satisfy 1<x<1.5 showing oxygen deficiency, are particularly suitable.

### Third Example

Next, as a third example of the present invention, the chemical stability of LaOₓ (x=1, 1.4375) and LaB₆ was estimated by the first-principle molecular dynamics simulation. In this case, in addition to the method of the first example described above, the Car-Parrinello method was adopted for the molecular dynamics part. The simulation was performed at a temperature of 500K, with water molecules placed at a distance of 4 Å from the surface. Quantum Espresso v7.0 (downloaded from https://www.quantum-espresso.org) was used for these calculations.

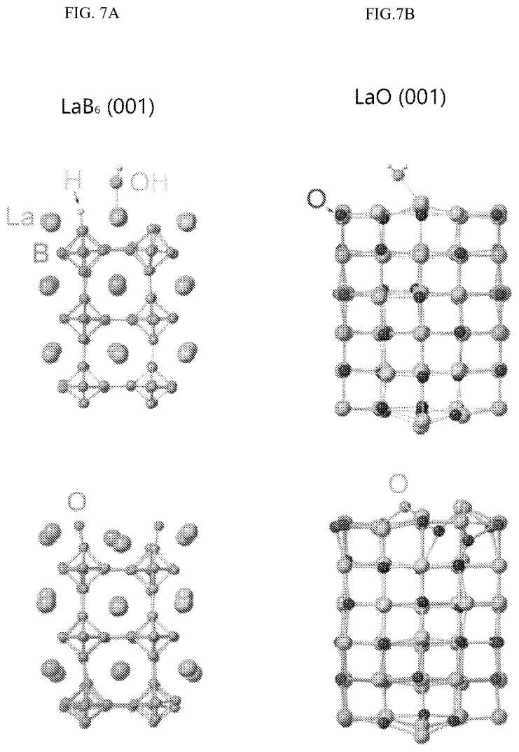

FIGS. 7A and 7B are views showing the results of molecular dynamics simulations, in which FIG. 7A shows the crystal of LaB₆ and the state of water molecules on its (001) plane, and FIG. 7B shows the crystal of LaO and the state of water molecules on its (001) plane. As shown in FIGS. 7A and 7B, water molecules (H₂O) were dissociated into H and OH and adsorbed on the (001) plane of LaB₆, but were not dissociated on the (001) plane of LaO. Although not shown, water molecules were not dissociated also on the (110) plane of hexagonal crystal system LaOₓ (x=1.14375), as with LaO. From this, it was found that REOₓ compounds (1≤x<1.5) are chemically stable compared to LaB₆, and it was confirmed that these compounds are effective for emitters.

### Fourth Example

Next, as a fourth example of the present invention, an emitter equipped with a nanoneedle was manufactured using LaOₓ (1<x<1.5) by the method shown in FIG. 3. Specifically, the surface of a metal made of La (manufactured by Kojundo Chemical Lab Co., Ltd., diameter 10 mm×thickness 2 mm) was oxidized to form a thin film of a rare earth oxide represented by LaOₓ (1<x<1.5). At that time, the La metal with the surface grinding-finished was kept in an environment of room temperature (20° C.), relative humidity 45%, and vacuum degree 100 Pa for two weeks.

X-ray diffraction was performed on the La metal after the oxidation treatment, and it was found that hexagonal crystal system polycrystalline LaOₓ (space group P63/mmc, a=0.39 nm, b=0.39 nm, c=0.61 nm) was formed on the surface. The thickness of LaOₓ determined by scanning electronic microscope (SEM) observation was 2.5 μm. Furthermore, the atomic ratio of O to La in the oxide film was examined by energy dispersive X-ray spectroscopy (EDX) attached with SEM, and it was calculated to be O/La=1.48. From the above, it was confirmed that a polycrystalline thin film (thickness 2.5 μm) of hexagonal crystal system LaOₓ (x=1.48) was formed on the surface of the La metal by the oxidation treatment.

Subsequently, the oxide film on the La metal surface was worked into a needle shape using a focused ion beam (FIB). Specifically, platinum (Pt) was vapor-deposited onto a certain area (15 μm×3 μm) of the LaOₓ thin film on the La metal, and then the periphery and bottom were ground and cut out to obtain a LaOₓ thin film piece. Then, a tungsten (W) tip was brought into contact with the surface of the cut out LaOₓ thin film piece, and Pt was vapor-deposited onto the contact point to fix the LaOₓ thin film piece to the tungsten tip.

Then, the LaOₓ thin film piece was picked up using a tungsten tip and placed on a tungsten support needle. At that time, a tungsten (W) needle having a radius of 100 nm, which was worked by FIB so that the end was flat, was used as the support needle. Thereafter, Pt was vapor-deposited to fix the LaOₓ thin film piece on the support needle, which was then cut at an appropriate position. In this way, the LaOₓ thin film piece (width 2 μm×depth 2 μm×height 2.5 μm) was fixed to the tungsten support needle.

Next, using an FIB system, a Ga ion beam was irradiated and scanned over the LaOₓ thin film piece under the conditions shown below.
Current: 790 pA
Voltage: 30 kV
Irradiation time: 10 minutes
Irradiation position: Scanning from the outside to the inside of the LaOₓ thin film piece
Environment: 10⁻⁵ to 10⁻³ Pa

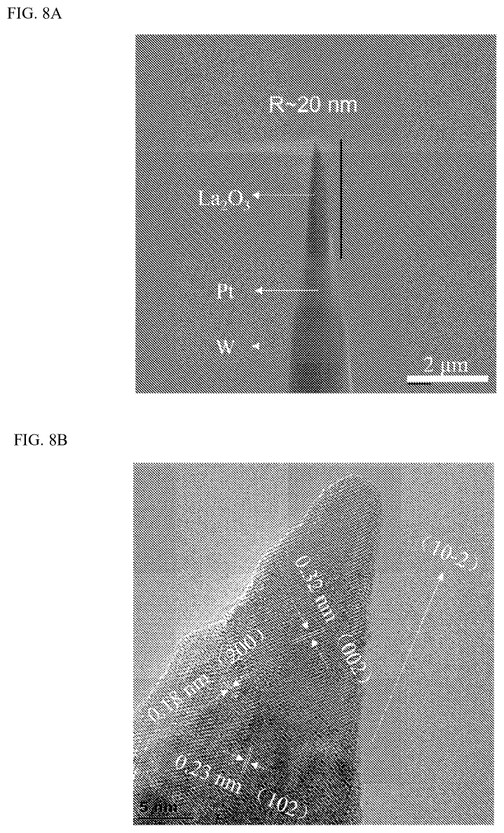

The LaOₓ nanoneedle formed by the above-mentioned method was observed by a scanning electronic microscope (Helios 650 manufactured by FEI Company Japan Ltd.) and a transmission electronic microscope (JEM-3100F manufactured by JEOL Ltd.). FIG. 8A is an SEM image of the LaOₓ nanoneedle, and FIG. 8B is a TEM image. As shown in FIG. 8A, a LaOₓ nanoneedle was formed on a tungsten support needle via Pt, the shape of which became thinner toward the tip. The maximum diameter d of this LaOₓ nanoneedle was 600 nm, and the curvature radius r of the tip was 20 nm, which was 3.3% of the maximum diameter d. Also, as shown in FIG. 8B, the tip of the LaOₓ nanoneedle was composed of a single crystal, and its crystal plane was (102 ).

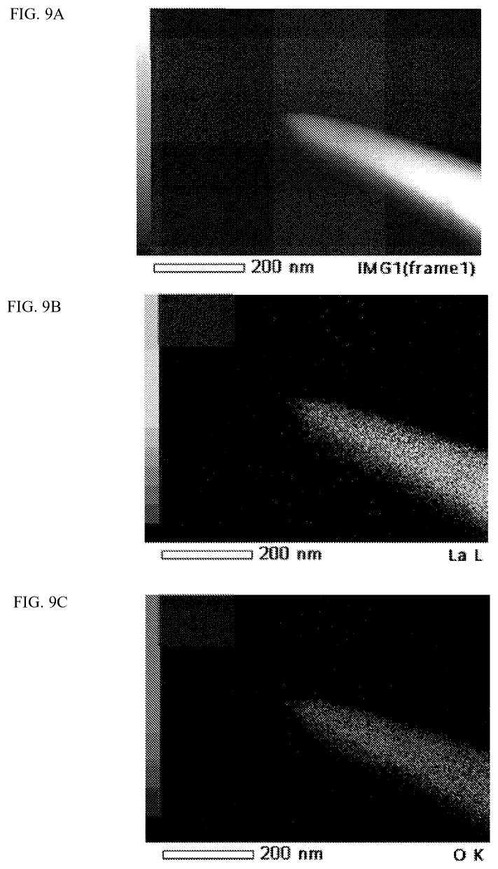

Next, the LaOₓ nanoneedle was observed by a scanning transmission electronic microscope and subjected to elemental analysis by EDS. The results are shown in Table 8 below. Also, FIGS. 9A to 9C are views showing STEM-EDS mapping of the LaOₓ nanoneedle. Note that FIGS. 9A to 9C are shown in grayscale, and the bright areas in FIGS. 9B and 9C indicate the presence of lanthanum (La) and oxygen (O), respectively. As shown in FIGS. 9A to 9C, the LaOₓ nanoneedle was substantially formed of La and O.

TABLE 8

| Element | Energy (keV) | Mass % | Atomic % |
|---|---|---|---|
| C | 0.277 | 0.01 | 0.04 |
| O | 0.525 | 14.20 | 58.39 |
| Ga | 9.241 | 2.12 | 2.00 |
| La | 4.650 | 83.18 | 39.40 |
| Pt | 2.048 | 0.50 | 0.17 |

As shown in Table 8, Pt was detected in the elemental analysis by EDS, which was due to the Pt used to fix the tungsten support needle and the LaOₓ nanoneedle. It was confirmed that the atomic ratio of La to O in the LaOₓ nanoneedle was 1.48 (=58.39/39.4), suggesting LaO_{1.48}. Furthermore, since Ga was used as an ion source, Ga was detected in the LaOₓ nanoneedle.

Next, the field emission characteristics of the LaOₓ nanoneedle were examined using a field emission microscope (FEM). The inside of a chamber was maintained at a high vacuum of 3×10⁻⁷ Pa, and thermal flashing was performed to clean the tip of the LaOₓ nanoneedle. Then, a negative voltage (750 V) was applied to the tip of the LaOₓ nanoneedle to induce electron emission. Subsequently, the polarity of the extraction voltage at the tip of the LaOₓ nanoneedle was reversed to perform field emission, and the field emission pattern was observed. Note that the field emission pattern was projected onto a screen (microchannel plate, diameter 1 cm) placed 5 cm away from the LaOₓ nanoneedle.

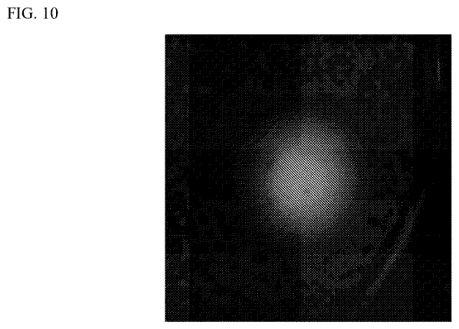

FIG. 10 is a view showing the field emission pattern of the LaOₓ nanoneedle. FIG. 10 shows the pattern in gray scale, and the bright areas are the areas where electrons collided with the screen, thus it was confirmed that the LaOₓ nanoneedle emits electric field and functions as an emitter. In particular, it was shown that the LaOₓ nanoneedle shows a single field emission pattern, being advantageous for increasing brightness.

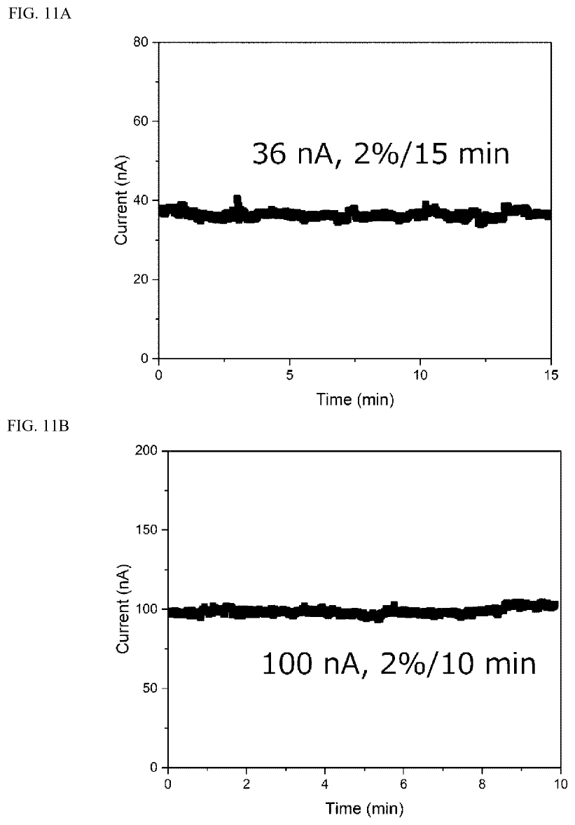

Furthermore, the tip of the LaOₓ nanoneedle was thermally flashed, and the current stability was measured under two conditions at room temperature: (A) current value: 36 nA, applied voltage: 750 V, and (B) current value: 100 nA, applied voltage: 800 V. FIGS. 11A and 11B are views showing the current stability of the LaOₓ nanoneedle. The current was stable under both the condition of current value: 36 nA, applied voltage: 750 V shown in FIG. 11A, and the condition of current value: 100 nA, applied voltage: 800 V shown in FIG. 11B. Then, the fluctuation of the emission current (<ΔI²>^{1/2}I) was evaluated and found to be 2%/15 minutes and 2%/10 minutes, respectively, which were significantly low values. This indicates that the LaOₓ nanoneedle of this example has excellent characteristics as an emitter.

From the above results, it was confirmed that the present invention can realize an emitter that can emit electrons highly efficiently and stably over a long period of time.

1. An emitter comprising a nanoneedle, wherein
the nanoneedle is formed of a rare earth oxide represented by the general formula REOₓ, where RE is a rare earth element and 1≤x<1.5.

2. The emitter according to claim 1, wherein
at least the tip of the nanoneedle is composed of a crystalline phase.

3. The emitter according to claim 2, wherein
the crystalline phase is at least one crystal system selected from the group consisting of a cubic crystal system, a monoclinic crystal system, and a hexagonal crystal system.

4. The emitter according to claim 3, wherein
when the crystalline phase is a cubic crystal system, the crystal plane of the tip of the nanoneedle is a (001) plane or a (110) plane,
when the crystalline phase is a monoclinic crystal system, the crystal plane of the tip of the nanoneedle is a (010) plane, and
when the crystalline phase is a hexagonal crystal system, the crystal plane of the tip of the nanoneedle is a (102 ) plane.

5. The emitter according to claim 1, wherein
the rare earth oxide contains at least one rare earth element selected from the group consisting of La, Ce, Pr, Nd, and Sm.

6. The emitter according to claim 1, wherein
the rare earth oxide contains Ga in an amount of 0.5 atomic % or less.

7. The emitter according to claim 1, wherein
the nanoneedle has a maximum diameter of 1 nm or more and 1 μm or less and a length of 500 nm or more and 30 μm or less.

8. The emitter according to claim 7, wherein
the curvature radius of the tip of the nanoneedle is less than or equal to 50% of the maximum diameter.

9. The emitter according to claim 8, wherein
the curvature radius of the tip of the nanoneedle is 5 to 30 nm.

10. The emitter according to claim 1,
further comprising a support needle and a filament, wherein
the support needle is composed of at least one element selected from the group consisting of W, Ta, Pt, Re, and C, and
the nanoneedle is attached to the filament via the support needle.

11. An electron gun comprising the emitter as described in claim 1.

12. The electron gun according to claim 11, which is a cold cathode field emission electron gun or a Schottky electron gun.

13. An electronic apparatus comprising the electron gun according to claim 11.

14. A method for manufacturing an emitter comprising a nanoneedle, comprising:
a process of oxidizing the surface of a metal containing a rare earth element to form a film composed of a rare earth oxide represented by the general formula REOₓ (wherein RE is a rare earth element and 1≤x<1.5), and
a process of working the film composed of the rare earth oxide into a needle shape using a focused ion beam to obtain the nanoneedle.

15. The method for manufacturing an emitter according to claim 14, wherein
in the process of forming a film composed of a rare earth oxide, the surface of a metal containing a rare earth element is oxidized by holding the metal under conditions of a temperature of 0 to 800° C., a pressure of 10¹ to 10⁵ Pa, and a relative humidity of 10 to 70%.

16. The method for manufacturing an emitter according to claim 14, wherein
in the process of working the film composed of the rare earth oxide into a needle shape, the film composed of the rare earth oxide is cut out from the surface of the metal and the film composed of the rare earth oxide is placed on a support needle.
